(19) United States
(12) Patent Application Publication
(10) Pub. No.: US 2021/0233585 A1
(43) Pub. Date: Jul. 29, 2021

(54) MULTICHIP MEMORY PACKAGE WITH INTERNAL CHANNEL

(71) Applicant: Micron Technology, Inc., Boise, ID (US)

(72) Inventors: Andrea Vigilante, Milano (MI) (IT); David A. Palmer, Boise, ID (US)

(21) Appl. No.: 16/776,402

(22) Filed: Jan. 29, 2020

(51) Int. Cl. G11C 14/00; G06F 3/06; G06F 13/16; G06F 11/10

(52) U.S. Cl. CPC G11C 14/0018; G06F 3/0604; G06F 11/1004; G06F 3/068; G06F 13/1668; G06F 3/0659

(57) ABSTRACT

Methods, systems, and devices for multichip memory packages are described. A multichip memory package may include at least two dies that include different types of memory, such as one die that includes non-volatile memory and another die that includes volatile memory. The package may include an in-package channel that supports internal data transfer between the two types of memory. For example, a respective controller for each of the types of memory may also be included in the package and may be coupled with each other via the in-package interface. In some cases, data may be read from one of the types of memory and written to the other type of memory in response to a single read or write command and without passing over any interface outside of the package.

### BACKGROUND

The following relates generally to a system that includes at least one memory device and more specifically to multichip memory packages.

Memory devices are widely used to store information in various electronic devices such as computers, wireless communication devices, cameras, digital displays, and the like. Information is stored by programming different states of a memory device. For example, binary devices most often store one of two states, often denoted by a logic 1 or a logic 0. In other devices, more than two states may be stored. To access the stored information, a component of the device may read, or sense, at least one stored state in the memory device. To store information, a component of the device may write, or program, the state in the memory device.

Various types of memory devices exist, including magnetic hard disks, random access memory (RAM), read-only memory (ROM), not-and (NAND) memory, dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory, e.g., NAND, may maintain their stored logic state for extended periods of time even in the absence of an external power source. Volatile memory devices, e.g., DRAM, may lose their stored state when disconnected from an external power source.

In some memory configurations, a host device may communicate with multiple types of memory storage (e.g., volatile and non-volatile memory) in order to perform one or more access operations (e.g., read or write operations). Some configurations for communications between the host device and the multiple types of memory storage may introduce latency and increase power consumption.

### BRIEF DESCRIPTION OF THE DRAWINGS

FIG. 1 illustrates an example of a system that supports multichip memory packages in accordance with examples as disclosed herein.

FIG. 2 illustrates an example of a memory system that supports multichip memory packages in accordance with examples as disclosed herein.

FIG. 3 illustrates an example of a memory system that supports multichip memory packages in accordance with examples as disclosed herein.

FIG. 4 illustrates an example of a process flow that supports multichip memory packages in accordance with examples as disclosed herein.

FIG. 5 illustrates an example of a process flow that supports multichip memory packages in accordance with examples as disclosed herein.

FIG. 6 shows a block diagram of a memory device that supports multichip memory packages in accordance with aspects of the present disclosure.

FIGS. 7 through 10 show flowcharts illustrating a method or methods that support multichip memory packages in accordance with examples as disclosed herein.

### DETAILED DESCRIPTION

A memory device may be or include a multichip package (MCP), where a single package includes multiple memory dice, which may alternatively be referred to as chips. Each die may include one or more memory arrays. For example, a memory device may include two or more memory units, where a memory unit as used herein may refer to one or more dice including a respective type of memory (e.g., volatile or non-volatile memory). A memory unit may also include an interface for communicating with a host device and may, in some cases, communicate with the host device independently of other memory units associated with the memory device. Where a memory device includes multiple memory units, the memory units may exchange information with the host device via separate logical interfaces, which may or may not be implemented using separate physical interfaces. In some cases, a host device may read data from one memory unit (e.g., a non-volatile memory unit) in a memory device and then write that data to a second memory unit (e.g., a volatile memory unit) within the same memory device. Thus, the data may be transferred out of and then back into the same memory device (e.g., MCP), which may introduce undesired amounts of latency and power consumption.

As described herein, a memory device may be configured to include an in-package communications channel whereby two or more memory units within the memory device may directly communicate with one another. Dies coupled with the in-package channel may include a corresponding interface for communicating via the channel. A memory unit thus may use a respective in-package interface to communicate data and other information with other memory units included in the same package. For example, an in-package interface may be included in or coupled with a controller or another portion of a corresponding memory unit. In-package interfaces and in-package channel(s) as described herein may support a reduction in data transfers between the host device and the memory device and an associated reduction in power consumption and latency along with overhead for the host device, among other benefits that may be appreciated by those of ordinary skill in the art. For example, the in-package interfaces and the in-package channel(s) may be used to transfer data directly from a first memory unit to a second memory unit, or vice versa (e.g., when executing a read command associated with the first memory unit or a write command associated with the first memory unit). Such communications may take place between memory units without including the host device in the data transfer process. As such, the host device and the memory device may perform less steps for a given communication process, thus reducing latency, power consumption, and host device overhead.

In some examples, a memory array of a memory unit may be divided into one or more sections or partitions to store data received from one or more other memory units. A memory unit may use the one or more partitions, or other memory storage, to store data associated with the one or more other memory units. For example, such data may include mapping data, parity management data, or system data.

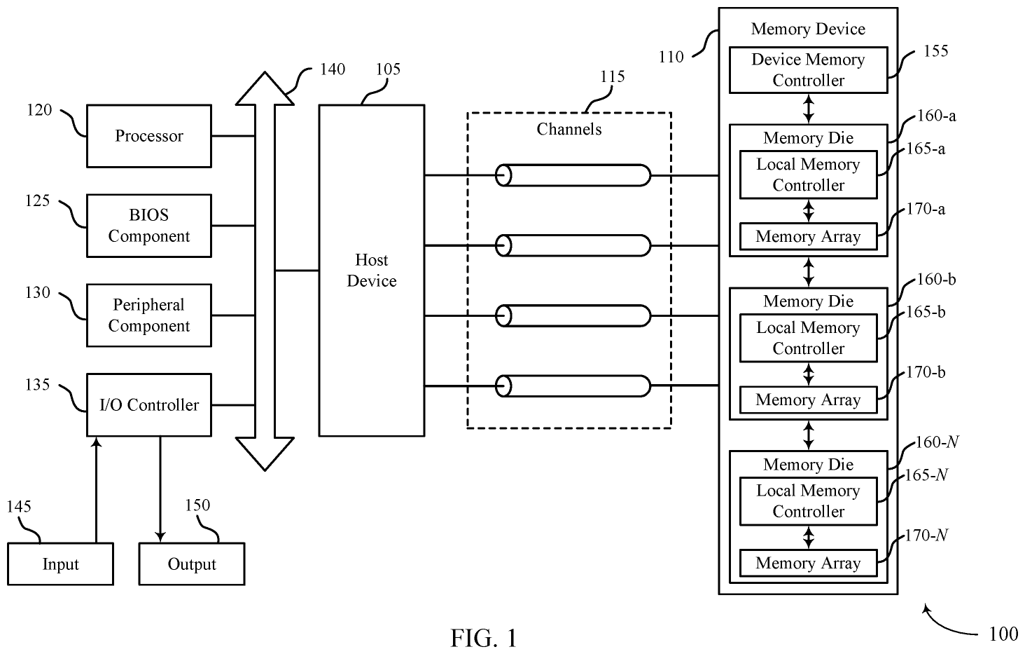

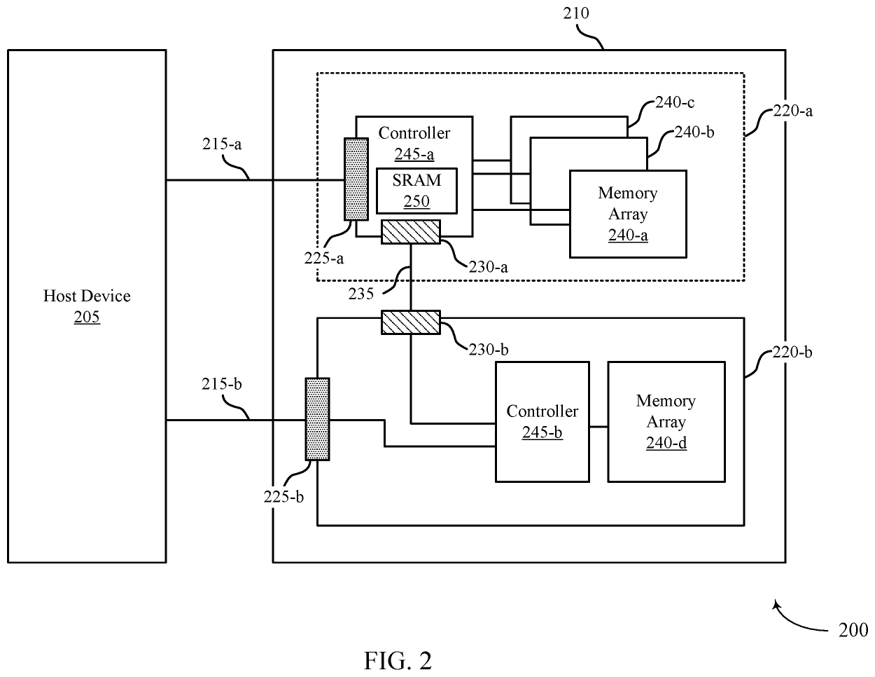

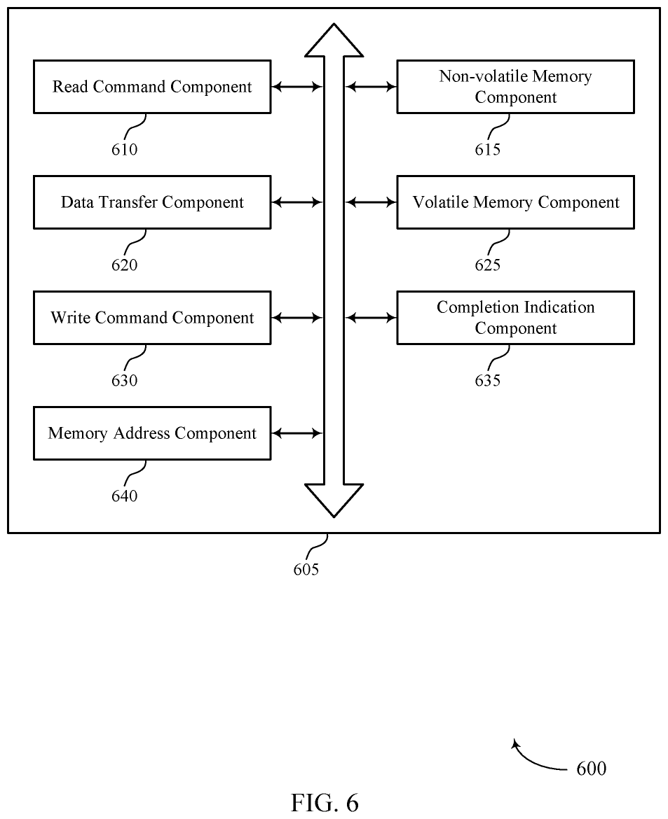

Features of the disclosure are initially described in the context of a memory system as described with reference to FIG. 1. Features of the disclosure are described in the context of systems and process flows as described with reference to FIGS. 2-5. These and other features of the disclosure are further illustrated by and described with reference to an apparatus diagram and flowcharts that relate to multichip memory packages as described with references to FIGS. 6-10.

FIG. 1 illustrates an example of a system 100 that utilizes one or more memory devices in accordance with examples as disclosed herein. The system 100 may include an external memory controller or host device 105, a memory device 110, and one or more channels 115 coupling the host device 105 with the memory device 110. The system 100 may include one or more memory devices, but for ease of description the one or more memory devices may be described as a single memory device 110. In some examples, the memory device 110 may be or include an MCP, and may include multiple types of memory, such as volatile and non-volatile memory, in the form of one or more memory units within a single package (e.g., mounted on (coupled with) a single substrate). In some cases, the examples described herein relating to the memory device 110 may additionally or alternatively apply to an individual memory unit of the memory device 110.

The system 100 may be or include portions of an electronic device, such as a computing device, a mobile computing device, a wireless device, or a graphics processing device. The system 100 may be an example of a portable electronic device. The system 100 may be an example of a computer, a laptop computer, a tablet computer, a smartphone, a cellular phone, a wearable device, an internet-connected device, or the like. The memory device 110 may be a component of the system configured to store data for one or more other components of the system 100.

At least portions of the system 100 may be examples of the host device 105. The the host device 105 may refer to the hardware, firmware, software, or a combination thereof that implements the functions of the external memory controller for the memory device 110. According to some aspects of the present disclosure, the host device 105 may be coupled with the memory device 110 and thus with one or more memory units therein, for communication and data transfer. The host device 105 may be configurable to transmit a read command or a write command to one memory unit of the memory device 110, and the read or write command may include information relating to or an indication for the memory unit to directly transfer (via an in-package interface) data to or request data from (via an in-package interface) a second memory unit of the memory device 110.

In some cases, a memory device 110 may be an independent device or component that is configured to be in communication with other components of the system 100 and provide physical memory addresses/space to potentially be used or referenced by the system 100. In some examples, a memory device 110 may be configurable to work with at least one or a plurality of different types of systems 100. Signaling between the components of the system 100 and the memory device 110 may be operable to support modulation schemes to modulate the signals, different pin designs for communicating the signals, distinct packaging of the system 100 and the memory device 110, clock signaling and synchronization between the system 100 and the memory device 110, timing conventions, and/or other factors.

The memory device 110 may be configured to store data for the components of the system 100. In some cases, the memory device 110 may act as a slave-type device to the system 100 (e.g., responding to and executing commands provided by the system 100 through the host device 105). Such commands may include an access command for an access operation, such as a write command for a write operation, a read command for a read operation, a refresh command for a refresh operation, or other commands. The memory device 110 may include two or more memory dice 160 (e.g., memory chips) to support a desired or specified capacity for data storage. Where the memory device 110 includes two or more memory dice with the same package, the memory device 110 may be referred to as an MCP.

The system 100 may further include a processor 120, a basic input/output system (BIOS) component 125, one or more peripheral components 130, and an input/output (I/O) controller 135. The components of system 100 may be in electronic communication with one another using a bus 140.

The processor 120 may be configured to control at least portions of the system 100. The processor 120 may be a general-purpose processor, a digital signal processor (DSP), an application-specific integrated circuit (ASIC), a field-programmable gate array (FPGA) or other programmable logic device, discrete gate or transistor logic, discrete hardware components, or it may be a combination of these types of components. In such cases, the processor 120 may be an example of a central processing unit (CPU), a graphics processing unit (GPU), a general purpose graphic processing unit (GPGPU), or a system on a chip (SoC), among other examples. As described below, in some cases the host device 105 may be implemented by or included in the processor 120.

The BIOS component 125 may be a software component that includes a BIOS operated as firmware, which may initialize and run various hardware components of the system 100. The BIOS component 125 may also manage data flow between the processor 120 and the various components of the system 100, e.g., the peripheral components 130, the I/O controller 135, etc. The BIOS component 125 may include a program or software stored in read-only memory (ROM), flash memory, or any other non-volatile memory.

The peripheral component(s) 130 may be any input device or output device, or an interface for such devices, that may be integrated into or with the system 100. Examples may include disk controllers, sound controller, graphics controller, Ethernet controller, modem, universal serial bus (USB) controller, a serial or parallel port, or peripheral card slots, such as peripheral component interconnect (PCI) or specialized graphics ports. The peripheral component(s) 130 may be other components understood by those skilled in the art as peripherals.

The I/O controller 135 may manage data communication between the processor 120 and the peripheral component(s) 130, input devices 145, or output devices 150. The I/O controller 135 may manage peripherals that are not integrated into or with the system 100. In some cases, the I/O controller 135 may represent a physical connection or port to external peripheral components.

The input 145 may represent a device or signal external to the system 100 that provides information, signals, or data to the system 100 or its components. This may include a user interface or interface with or between other devices. In some cases, the input 145 may be a peripheral that interfaces with system 100 via one or more peripheral components 130 or may be managed by the I/O controller 135.

The output 150 may represent a device or signal external to the system 100 configured to receive an output from the system 100 or any of its components. Examples of the output 150 may include a display, audio speakers, a printing device, or another processor on printed circuit board, and so forth. In some cases, the output 150 may be a peripheral that interfaces with the system 100 via one or more peripheral components 130 or may be managed by the I/O controller 135.

The components of system 100 may be made up of general-purpose or special purpose circuitry designed to carry out their functions. This may include various circuit elements, for example, conductive lines, transistors, capacitors, inductors, resistors, amplifiers, or other active or passive elements, configured to carry out the functions described herein.

The memory device 110 may include one or more device memory controllers 155 and one or more memory dice 160. Each memory die 160 may include a local memory controller 165 (e.g., local memory controller 165-a, local memory controller 165-b, and/or local memory controller 165-N) and a memory array 170 (e.g., memory array 170-a, memory array 170-b, and/or memory array 170-N). A memory array 170 may be a collection (e.g., a grid) of memory cells, with each memory cell being configured to store at least one bit of digital data. Some features of memory arrays 170 and/or memory cells are described in more detail with reference to FIG. 2.

The device memory controller 155 may include circuits or components configured to control operation of the memory device 110 or to control operation of one or more memory units of a memory device 110. As such, the device memory controller 155 may include the hardware, firmware, and software that enables the memory device 110 to perform commands and may be configured to receive, transmit, or execute commands, data, or control information related to the memory device 110. The device memory controller 155 may be configured to communicate with the external memory controller or the host device 105, the one or more memory dice 160, or the processor 120. In some cases, the memory device 110 may receive data and/or commands from the host device 105. For example, the memory device 110 may receive a write command indicating that the memory device 110 is to store certain data on behalf of a component of the system 100 (e.g., the processor 120) or a read command indicating that the memory device 110 is to provide certain data stored in a memory die 160 to a component of the system 100 (e.g., the processor 120).

In some cases, the device memory controller 155 may control operation of one or more memory units within the memory device 110 in conjunction with the local memory controllers 165 of the memory dice 160. Examples of the components included in the device memory controller 155 and/or the local memory controllers 165 may include cache memory, circuitry for implementing control and processing functionalities, receivers for demodulating signals received from the host device 105, decoders for modulating and transmitting signals to the host device 105, logic, decoders, amplifiers, filters, or the like. In some examples, a device memory controller 155 may communicate with the host device 105, such as via an interface and one or more channels. The device memory controller 155 may be configurable to communicate with another memory controller within a same memory device, or multiple memory arrays within a same memory device, to support communication between different memory units of the memory device.

The local memory controller 165 (e.g., local to a memory die 160) may be configured to control operations of the memory die 160. Also, the local memory controller 165 may be configured to communicate (e.g., receive and transmit data and/or commands) with the device memory controller 155. The local memory controller 165 may support the device memory controller 155 to control operation of the memory device 110 or memory unit as described herein. In some cases, the memory device 110 does not include the device memory controller 155, and the local memory controller 165 or the external memory controller or host device 105 may perform the various functions described herein. As such, the local memory controller 165 may be configured to communicate with the device memory controller 155, with other local memory controllers 165, or directly with the host device 105 or the processor 120. In some examples, a local memory controller 165 may communicate with the host device 105, such as via an interface and one or more channels. The local memory controller 165 may be configurable to communicate with another memory controller (e.g., another local memory controller 165 or a device memory controller 155) within a same memory device, or multiple memory arrays within a same memory device, to support communication between different memory units of the memory device.

The host device 105 may be configured to enable communication of information, data, and/or commands between components of the system 100 (e.g., the processor 120) and the memory device 110. The host device 105 may act as a liaison between the components of the system 100 and the memory device 110 so that the components of the system 100 may not need to know the details of the memory device's operation. The components of the system 100 may present requests to the host device 105 (e.g., read commands or write commands) that the host device 105 satisfies. The host device 105 may convert or translate communications exchanged between the components of the system 100 and the memory device 110. In some cases, the host device 105 may include a system clock that generates a common (source) system clock signal. In some cases, the host device 105 may include a common data clock that generates a common (source) data clock signal.

In some cases, the external memory controller or other component of the system 100, or its functions described herein, may be implemented by the processor 120. For example, the external memory controller may be hardware, firmware, or software, or some combination thereof implemented by the processor 120 or other component of the system 100. While the external memory controller is described as being external to the memory device 110, in some cases, the external memory controller, or its functions described herein, may be implemented by a memory device 110. For example, the external memory controller may be hardware, firmware, or software, or some combination thereof implemented by the device memory controller 155 or one or more local memory controllers 165. In some cases, the external memory controller may be distributed across the processor 120 and the memory device 110 such that portions of the external memory controller are implemented by the processor 120 and other portions are implemented by a device memory controller 155 or a local memory controller 165. Likewise, in some cases, one or more functions ascribed herein to the device memory controller 155 or local memory controller 165 may in some cases be performed by the external memory controller (either separate from or as included in the processor 120).

The components of the system 100 may exchange information with the memory device 110 using one or more channels 115. In some examples, the channels 115 may enable communications between the host device 105 and the memory device 110. Each channel 115 may include one or more signal paths or transmission mediums (e.g., conductors) between terminals associated with the components of system 100. For example, a channel 115 may include a first terminal including one or more pins or pads at the host device 105 and one or more pins or pads at the memory device 110. A pin may be an example of a conductive input or output point of a device of the system 100, and a pin may be configured to act as part of a channel.

In some cases, a pin or pad of a terminal may be part of a signal path of the channel 115. Additional signal paths may be coupled with a terminal of a channel for routing signals within a component of the system 100. For example, the memory device 110 may include signal paths (e.g., signal paths internal to the memory device 110 or its components, such as internal to a memory die 160) that route a signal from a terminal of a channel 115 to the various components of the memory device 110 (e.g., a device memory controller 155, memory dice 160, local memory controllers 165, memory arrays 170).

The channels 115 may couple the host device 105 with the memory device 110 using a variety of different architectures and protocols. Examples of the various architectures may include a bus, a point-to-point connection, a crossbar, a high-density interposer such as a silicon interposer, or channels formed in an organic substrate or some combination thereof. For example, in some cases, the signal paths may at least partially include a high-density interposer, such as a silicon interposer or a glass interposer. In some examples, a channel 115 may couple an interface on the host device 105 with an interface on a memory unit of the memory device 110 (e.g., with a controller of the memory unit). An in-package channel may also couple two or more memory units of the memory device 110 (e.g., couple interfaces of two or more memory units, such as interfaces coupled with a controller), such that the two or more memory units may transfer data or other information to each other without communicating through the host device 105. Data transfers transferred directly between memory units may include read data (e.g., associated with a read command), write data (e.g., associated with a write command), or the like.

Signals communicated over the channels 115 may be modulated using a variety of different modulation schemes. In some cases, a binary-symbol (or binary-level) modulation scheme may be used to modulate signals communicated between the host device 105 and the memory device 110. A binary-symbol modulation scheme may be an example of a M-ary modulation scheme where M is equal to two. Each symbol of a binary-symbol modulation scheme may be configured to represent one bit of digital data (e.g., a symbol may represent a logic 1 or a logic 0). Examples of binary-symbol modulation schemes include, but are not limited to, non-return-to-zero (NRZ), unipolar encoding, bipolar encoding, Manchester encoding, pulse amplitude modulation (PAM) having two symbols (e.g., PAM2), and/or others.

In some cases, a multi-symbol (or multi-level) modulation scheme may be used to modulate signals communicated between the host device 105 and the memory device 110. A multi-symbol modulation scheme may be an example of a M-ary modulation scheme where M is greater than or equal to three. Each symbol of a multi-symbol modulation scheme may be configured to represent more than one bit of digital data (e.g., a symbol may represent a logic 00, a logic 01, a logic 10, or a logic 11). Examples of multi-symbol modulation schemes include, but are not limited to, PAM3, PAM4, PAM8, etc., quadrature amplitude modulation (QAM), quadrature phase shift keying (QPSK), and/or others. A multi-symbol signal (e.g., a PAM3 signal or a PAM4 signal) may be a signal that is modulated using a modulation scheme that includes at least three levels to encode more than one bit of information per symbol. Multi-symbol modulation schemes and symbols may alternatively be referred to as non-binary, multi-bit, or higher-order modulation schemes and symbols.

As described herein, the memory device 110 may include multiple memory units within a single package along with an in-package interface that supports direction communications between two or more of the memory units of the memory device 110. The in-package interface may be coupled with one or more in-package channels, where the one or more in-package channels may support communications with the one or more other memory units. As such, the in-package interfaces and in-package channel(s) may support a reduction external communications with the host device 105 and an associated reduction in power consumption and latency. For example, the in-package interfaces and the in-package channel(s) may be used to transfer data from a first memory unit to a second memory unit of the memory device 110, or vice versa. In some examples, a memory array of a memory unit may be divided into one or more sections or partitions to store data received from the host device 105 and data received from one or more other memory units. A memory unit may use the one or more partitions, or other memory storage, to store data associated with the host device 105 or with another memory unit. Such data may include mapping data, parity management data, or system data.

FIG. 2 illustrates an example of a system 200 in accordance with examples as disclosed herein. The system 200 may be an example of the system 100 described with reference to FIG. 1. For example, system 200 may include a host device 205 that may be coupled with a memory device 210. The host device 205 and the memory device 210 may exchange data (e.g., corresponding to read or write commands) or other communications via one or more channels 215, which may be examples of one or more channels 115 described with reference to FIG. 1. In some cases, channel 215-a and channel 215-b may be separate logical channels that utilize different protocols but may be implemented as either separate physical channels or as a single physical channel.

Memory device 210 may be or include an MCP that includes multiple memory dice or memory arrays (e.g., in order to conserve space). For example, memory device 210 may include two or more memory units 220 (e.g., each memory unit 220 including one or more memory chips or dice). In one example, memory device 210 may include two memory units 220-a and 220-b, which may be examples of memory units 220 that correspond to different types of memory (e.g., non-volatile versus volatile). A memory unit 220 may include one or more memory dice or memory arrays 240 of a same type of memory storage, along with a related controller, which may be included in a separate die or may be included in a same die as a memory array 240.

Memory unit 220-a may correspond to a type of non-volatile memory (e.g., not- and (NAND) memory, ferroelectric memory, phase change memory (PCM), etc.) and memory unit 220-b may correspond to a type of volatile memory (e.g., random access memory (RAM), dynamic RAM (DRAM), synchronous dynamic RAM (SDRAM), etc.). Each memory unit 220 may include one or more dice of memory (e.g., including memory arrays 240) corresponding to a type of memory associated with the memory unit 220. In some cases, each memory unit may also include a controller 245 that may be an example of a local memory controller or a device memory controller as described with reference to FIG. 1. In some cases, one of the memory units 220 may include a controller 245 that may function as a controller for both memory units 220. A controller 245 may also be referred to as logic and arbiter circuitry to support the use of multiple interfaces 230-b, 225-b as discussed herein (e.g., with respect to a volatile memory unit 220, such as DRAM). In some examples, a controller 245 or functions of a controller 245 may be included in one or more dice of a memory array 240 of a memory unit 220. In some examples, a controller 245 or functions of a controller 245 may be included in one or more dedicated dice of a memory unit 220 (e.g., one or more dice of the memory unit may be dedicated to controller functions).

For example, controller 245-a, or functions of controller 245-a, may be included in one or more memory dice of memory unit 220-a (e.g., memory dice including one or more of memory arrays 240-a, 240-b, or 240-c). Additionally or alternatively, one or more dice of memory unit 220-a may be dedicated to functions for controller 245-a. Similarly, controller 245-b, or functions of controller 245-b, may be included in one or more memory dice of memory unit 220-b (e.g., memory dice including memory array 240-d). Additionally or alternatively, one or more dice of memory unit 220-b may be dedicated to functions for controller 245-b.

In some examples, memory unit 220-a may include non-volatile memory in the form of NAND memory (e.g., including multiple NAND memory cells). In some examples, the NAND memory may additionally represent managed NAND (MNAND) memory, in which memory unit 220-a may include a dedicated controller 245-a to control the NAND memory arrays 240. The controller 245-a may be included in a separate die. The controller 245-a may be a universal flash storage (UFS) controller or may be an embedded multimedia controller (eMMC), among other examples, and the controller 245-a may exchange information with the host device 205 via the channel 215-a in accordance with a UFS or eMMC protocol, as applicable. The controller 245-a may include embedded synchronous RAM (SRAM) or other memory as a cache, which may support performing one or more of the controller or other functions described herein.

In some NAND memory architectures, a memory cell may include a transistor (e.g., a metal-oxide-semiconductor (MOS) transistor) that has a floating gate and/or may include a dielectric material for storing a charge representative of the logic state. A transistor may have a control gate, a first node (e.g., a source or drain), and a second node (e.g., a drain or source), and may further include a floating gate that is sandwiched between dielectric material. A logic state may be stored in the transistor by placing (e.g., writing, storing) a quantity of electrons (e.g., a charge) on the floating gate. The amount of charge to be stored on the floating gate may depend on the logic state to be stored. The charge stored on the floating gate may affect the threshold voltage of the transistor, thereby affecting the amount of current that may flow through the transistor when the transistor is activated. The logic state stored in the transistor may be read by applying a voltage to the control gate (e.g., at a control node) to activate the transistor and measuring (e.g., detecting, sensing) the resulting amount of current that flows between the first node and the second node.

For example, a sense component may determine whether a single-level NAND memory cell stores a logic state 0 or a logic state 1 in a binary manner; e.g., based on the presence or absence of a current from the memory cell, or based on whether the current is above or below a threshold current. For multiple-level NAND cells, however, a sense component may determine the logic state stored in the memory cell based on various intermediate levels of current. Similarly, a single-level NAND memory cell may be written by applying one of two voltages (e.g., a voltage above a threshold or a voltage below a threshold) to the memory cell to store (or not store) an electric charge on the floating gate representing one of the two possible logic states. In contrast, a multiple-level NAND cell may be written to by applying voltages at a finer level of granularity to more finely control the amount of charge stored on the floating gate, thereby enabling a larger set of logic states to be represented.

A charge-trapping NAND memory cell may operate in a manner similar to that of a floating-gate NAND memory cell, but instead of (or in addition to) storing a charge on a floating gate, a charge-trapping Flash memory cell may store a charge representing the state in a dielectric material (e.g., below the control gate). Thus, a charge-trapping NAND memory cell may or may not include a floating gate.

In one example, memory unit 220-b may represent a memory device including volatile memory in the form of DRAM memory (e.g., including multiple DRAM memory cells). In some examples, memory unit 220-b may represent low power DRAM (LPDRAM). The controller 245-b may exchange information with the host device 205 via the channel 215-b in accordance with a corresponding protocol, such as an LPDDR (low-power double data rate) or other protocol, as applicable.

A DRAM memory cell may store a charge representative of its programmable states (e.g., two or more states) in a capacitor. DRAM architectures may include a capacitor that includes a dielectric material to store a charge representative of the programmable state. In other memory architectures, other storage devices and components are possible. For example, nonlinear (e.g., ferroelectric) dielectric materials or other materials may be employed. A DRAM memory cell may include a logic storage component, such as capacitor, and a switching component.

During a read operation, a capacitor of a DRAM memory cell may output a signal (e.g., discharge a charge) to a corresponding line (e.g., a digit line). The signal may cause a voltage of the line to change. A sense component may be configured to compare the signal received from the memory cell to a reference signal (e.g., reference voltage). The sense component may determine the stored state of the memory cell based on the comparison. For example, in binary-signaling, if the line has a higher voltage than the reference signal, the sense component may determine that the stored state of memory cell is a logic 1 and, if the line has a lower voltage than the reference signal, the sense component may determine that the stored state of the memory cell is a logic 0. In some cases, multiple memory cells may be sensed during a single read operation.

During a write operation, a memory cell may be programmed to store a desired logic state. In some cases, multiple memory cells may be programmed during a single write operation. In a write operation, a controller may activate one or more lines (e.g., by applying a voltage to a word line and/or a digit line), to access a target memory cell. The controller may apply a specific signal (e.g., voltage) to the memory cell, via a line, during the write operation to store a specific state (e.g., charge) in the capacitor of the memory cell. The specific state (e.g., charge) may be indicative of a desired logic state.

In some cases, a volatile or non-volatile memory array may include a three-dimensional (3D) memory array, where multiple two-dimensional (2D) memory arrays are formed on top of one another. This may increase the quantity of memory cells that may be placed or created on a single die or substrate as compared with 2D arrays, which in turn may reduce production costs, or increase the performance of the memory array, or both. The levels may, in some examples, be separated by an electrically insulating material. Each level may be aligned or positioned such that memory cells may be aligned (exactly, overlapping, or approximately) with one another across each level, forming a memory cell stack. In some cases, a memory cell stack may be referred to as a string of memory cells.

In some examples of volatile or non-volatile memory, each row of memory cells may be connected to a word line and each column of memory cells may be connected to a digit line. Thus, one memory cell may be located at the intersection of a word line and a digit line. This intersection may be referred to as a memory cell's address. Digit lines are sometimes referred to as bit lines. In some cases, word lines and digit lines may be substantially perpendicular to one another and may create an array of memory cells. In some cases, word lines and digit lines may be generically referred to as access lines or select lines.

References to access lines, word lines, and digit lines, or their analogues, are interchangeable without loss of understanding or operation. Activating or selecting a word line or a digit line may include applying a voltage to the respective line.

Accessing volatile or non-volatile memory cells may be controlled through a row decoder and column decoder. For example, a row decoder may receive a row address from a controller and activate an appropriate word line based on the received row address. Similarly, a column decoder may receive a column address from a memory controller and activate an appropriate digit line. Thus, by activating one word line and one digit line, one memory cell may be accessed. Upon accessing, a memory cell may be read, or sensed, by a sense component. For example, a sense component may be configured to determine the stored logic state of the memory cell based on a signal generated by accessing the memory cell. The signal may include a voltage or electrical current, or both, and sense component may include voltage sense amplifiers, current sense amplifiers, or both.

A sense component may include various transistors or amplifiers in order to detect and amplify a signal (e.g., a current or voltage) on a digit line or other access line. The detected logic state of memory cell may then be output via an input/output block. In some cases, a sense component may be a part of a column decoder or row decoder, or a sense component may otherwise be connected to or in electronic communication with a column decoder or a row decoder. A memory cell may be set or written by similarly activating the relevant word line and digit line to enable a logic state (e.g., representing one or more bits of information) to be stored in the memory cell. A column decoder or a row decoder may accept data, for example from an input/output block, to be written to the memory cells.

One or more controllers may control the operation (e.g., read, write, re-write, refresh) of the volatile or non-volatile memory cells through the components described herein, for example, a row decoder, a column decoder, and a sense component. In some cases, one or more of a row decoder, a column decoder, and a sense component may be co-located with the controller. The controller may generate row and column address signals in order to activate a desired word line and digit line. The controller may also generate and control various voltages or currents used during the operation of a memory device (e.g., memory device 210, memory unit 220-a or 220-b, etc.).

A memory unit 220 may include an interface 225 for communicating with the host device 205 via a channel 215 and may, in some cases, communicate with the host device 205 independently of other memory units 220 associated with the memory device 210. For example, memory unit 220-a may communicate with host device 205 (e.g., via interface 225-a) independently of memory unit 220-b, and vice versa. The interface 225 may, in some cases, be included in or coupled with a controller 245 of the corresponding memory unit 220. The interface may also be coupled with one or more channels 215 or physical entities (e.g., signal paths) associated with a channel 215, where the one or more channels 215 may support communications with the host device 205. A physical entity associated with a channel may be or include one or more lines (e.g., conductive lines), traces, wires, or other signal-bearing entity.

According to some aspects of the present disclosure, a memory unit 220 may also include at least one in-package interface 230 for communicating with one or more other memory units 220 via an in-package channel. For example, memory units 220-a and 220-b may include in-package interfaces 230-a and 230-b, respectively. Memory units 220-a and 220-b may use their respective in-package interface 230 for communicating data and other information with each other. In some cases, an in-package interface 230 may be included in or coupled with a controller 245 of a corresponding memory unit 220. An in-package interface 230 may be a parallel interface or a serial interface (e.g., a high-speed serial interface). The in-package interface 230 may also be coupled with one or more in-package channels 235 or physical entities associated with an in-package channel 235, where the one or more in-package channels 235 may support communications between the one or more other memory units 220. The in-package interfaces 230 and the one or more corresponding in-package channels 235 may be included within memory device 210 (e.g., within the MCP). Although FIG. 2 illustrates an example of in-package interfaces 230 and an in-package channel 235 coupling two memory units 220, the same principles may apply to more than two memory units included in a memory device 210 (e.g., in an MCP).

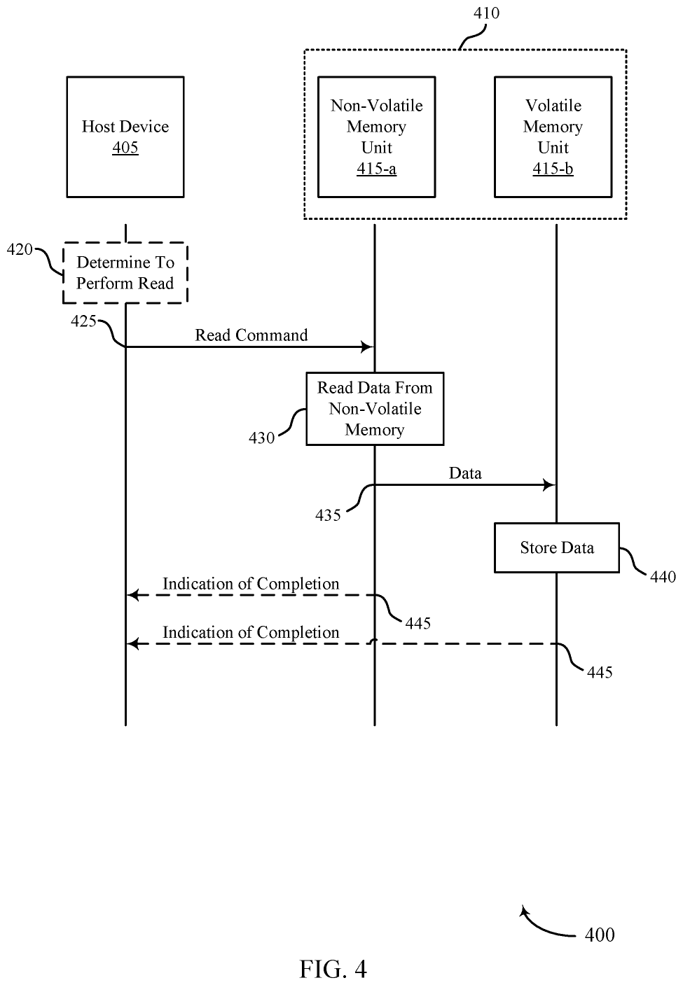

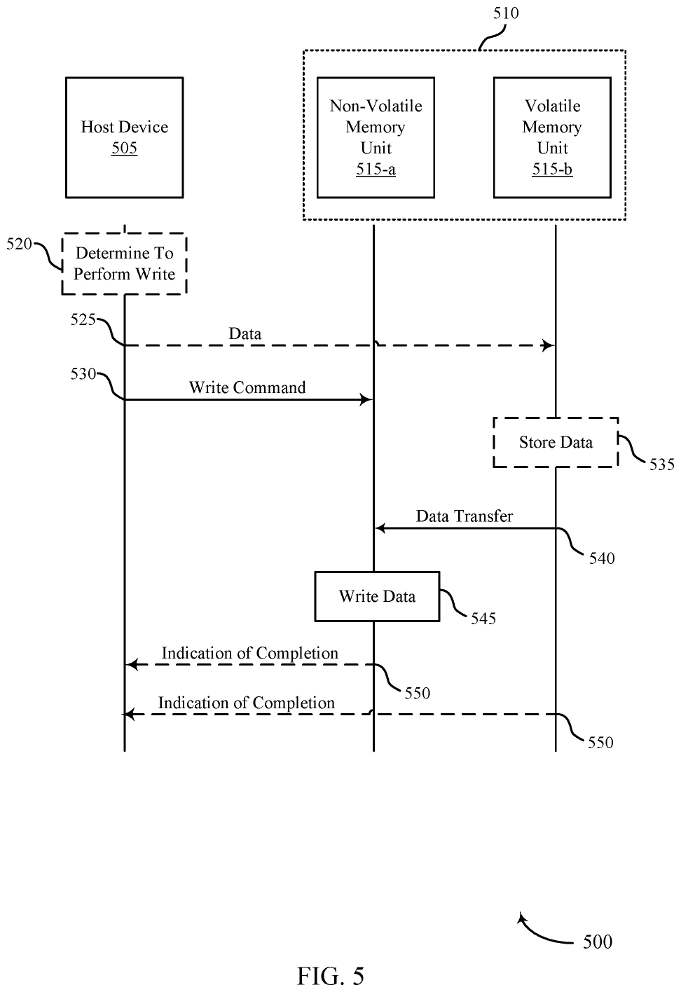

The in-package interfaces 230 and corresponding in-package channel(s) 235 may support direct communication (e.g., data transfer) between memory units 220 of a memory device 210. As such, the in-package interfaces 230 and in-package channel(s) 235 may support a reduction in data transfers between the host device 205 and memory device 210, and thus may reduce overhead for the host device 205 while also reducing power consumption and latency. For example, in-package interfaces 230 and in-package channel(s) 235 may be used to transfer data from memory unit 220-a to memory unit 220-b (e.g., when executing a read command to read data from memory unit 220-a) or to transfer data from memory unit 220-b to memory unit 220-a (e.g., when executing a write command to write data to memory unit 220-a). Communications may take place between memory units 220-a and 220-b without including the host device 205 in the data transfer process, and without data passing outside of the memory device 210 (that is, without passing outside of the MCP package). An example read command process (for reading data from memory unit 220-a) is described with reference to FIG. 4 and an example write command process (for writing data to memory unit 220-a) is described with reference to FIG. 5.

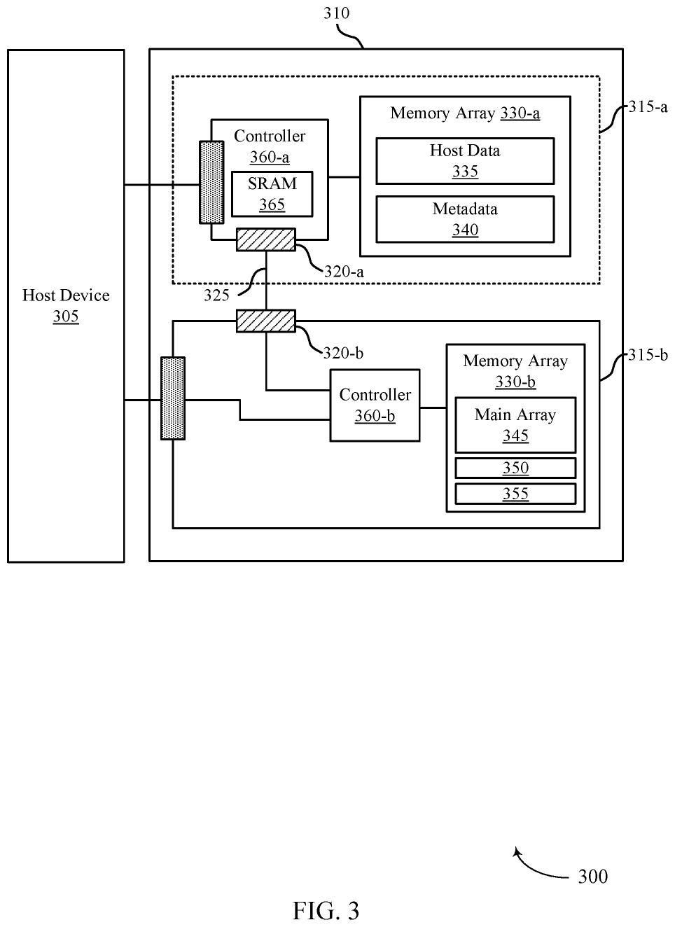

In some examples, a memory array 240 (e.g., memory array 240-d) of a memory unit (e.g., memory unit 220-b) may be divided into one or more sections or partitions to store data received from one or more other memory units 220 (e.g., memory unit 220-a). The divisions and partition or section use are further described with reference to FIG. 3. A memory unit 220 may use one or more partitions, or other memory storage, to store one or more types of data associated with another memory unit 220. Such data may include mapping data, parity management data, or system data.

FIG. 3 illustrates an example of a memory system 300 that supports multichip memory packages in accordance with examples as disclosed herein. The memory system 300 may be an example of the system 100 described with reference to FIG. 1 or may be an example of the system 200 described with reference to FIG. 2. For example, memory system 300 may include a host device 305 that may be coupled with a memory device 310. Memory device 310 may be or include an MCP that includes multiple memory dice or memory arrays. For example, memory device 310 may include two or more memory units 315 (e.g., each memory unit 315 including one or more memory chips, memory dice, or memory arrays). In one example, memory device 310 may include two memory units 315-a and 315-b, which may be examples of memory units 315 that correspond to different types of memory. A memory unit 315 may be an example of a memory unit 220 described with reference to FIG. 2.

As described with reference to FIG. 2, memory unit 315-a may correspond to a type of non-volatile memory (e.g., NAND memory, ferroelectric memory, PCM, etc.) and memory unit 315-b may correspond to a type of volatile memory (e.g., RAM, DRAM, SDRAM, etc.). In some cases, each memory unit 315 may also include a controller 360, where a controller 360 may be included on a separate die of the memory unit 315 or may share a die with portions of a memory array 330 of the memory unit 315. As described with reference to FIG. 2, a memory unit 315 may also include an in-package interface 320 for communicating with one or more other memory units 315. For example, memory units 315-a and 315-b may include in-package interfaces 320-a and 320-b, respectively. The in-package interface 320 may be coupled with one or more in-package channels 325 or physical entities associated with an in-package channel 325, where the one or more in-package channels 325 may support communications with the one or more other memory units 315. Although FIG. 3 illustrates an example of in-package interfaces 320 and an in-package channel 325 coupling two memory units 315, the same principles may apply to more than two memory units 315 included in a memory device 310 (e.g., may be used to couple the memory units 315).

In some examples, a memory array 330 of a memory unit 315 may be divided into two or more partitions to store data received from one or more other memory units 315. For example, memory array 330-b (e.g., a volatile memory array 330) may be partitioned into a main array 345, a shared host data buffer 350, and a non-volatile memory data cache 355, among other examples. The main array 345 may be accessible by the host device 305 and by memory unit 315-a and may include general volatile memory storage used by the host device 305 and accessible to memory unit 315-a to execute read and write commands (e.g., with respect to memory unit 315-a or memory unit 315-b). The shared host data buffer 350 may also be accessible by the host device 305 and by memory unit 315-a and may include general volatile memory storage used by the host device 305 and accessible to memory unit 315-a to execute read and write commands. The shared host data buffer 350 may, in some cases, represent a buffer used to temporarily store data for data transfers (e.g., read or write commands), in which the data may be inaccessible to one or more memory units 315 (e.g., memory unit 315-a) after completing a corresponding command. For example, the data may be deleted, erased, or cached in a different section after completing the corresponding command. In contrast, data in the main array 345 may be available after executing a corresponding command, such that the data in the main array 345 may be read or written one or more times after completing a corresponding command (e.g., a data transfer command, such as a read or write command). The non-volatile memory data cache 355 may represent a portion or a partition of memory array 330-b available for storing metadata or other data associated with one or more other memory arrays 330 (e.g., memory array 330-a) of memory unit 315-a. For example, the non-volatile memory data cache 355 may store mapping information, parity management information, non-volatile system data, or the like.

In one example, controller 360-a may be associated with non-volatile memory array 330-a, and controller 360-a may include SRAM 365 to store controller-type data or metadata. A memory storage capacity of the SRAM 365 (e.g., two to four megabytes (MB)) may be relatively small when compared with a capacity of the volatile memory array 330-b. As such, controller data or metadata for memory array 330-a may additionally or alternatively be stored in memory array 330-b (e.g., in the non-volatile memory data cache 355). Controller data or metadata may refer to data related to the management of non-volatile memory array 330-a by controller 360-a, such as address mapping data, parity (e.g., error correction) data, state information, erase cycle counters, garbage collection data, or other data related to the management of non-volatile memory array 330-a. In some cases, host data 335 (e.g., stored non-volatile data) and metadata 340 may be stored in memory array 330-a, but the metadata 340 may be accessed relatively slowly when compared with data in memory array 330-b. As such, some metadata for memory array 330-a may additionally or alternatively be stored in memory array 330-b (e.g., in the non-volatile memory data cache 355).

As a first example, memory array 330-b may store a logical-to-physical (L2P) data map or table for memory array 330-a, which may map logical addresses associated with data to physical addresses within memory array 330-a, such that the mapping data may be offloaded to memory array 330-b (e.g., in the non-volatile memory data cache 355). As such, the host device 305 may be uninvolved with coordinating transfers of L2P data, which memory unit 315-a may receive directly from memory unit 315-b (e.g., via in-package interfaces 320-a and 320-b and one or more in-package channels 325). This offloading of interactions with the host device 305 may decrease complexity for the host device 305 and increase an amount of memory storage space available for the L2P data. Memory unit 330-a may identify L2P or other mapping data and may transfer the data (e.g., autonomously) to memory unit 330-b for storage in the non-volatile memory data cache 355, via the in-package interfaces 320-a and 320-b and the one or more in-package channels 325.

As a second example, memory array 330-b may additionally or alternatively store state or system information for memory unit 315-a. Memory unit 315-a may spend a majority of active time (e.g., 95 percent) in a sleep mode or a low power mode. When memory unit 315-a is in such a mode, state or system information may be stored within non-volatile memory array 330-a (e.g., or within controller 360-a) to support a later exit or wakeup from the mode, but data stored within non-volatile memory array 330-a may be slower to access than data stored within volatile memory array 330-b. As such, state or system information may be stored in memory array 330-b (e.g., in the non-volatile memory data cache 355) as part of or in preparation for memory unit 315-a entering the sleep or low power mode, which may increase an access speed for state or system information when loading such information to controller 360-a when memory unit 315-a exits (wakes up from) the sleep or low power mode. The information may be transferred from memory unit 315-b to memory unit 315-a via in-package interfaces 320-a and 320-b and one or more in-package channels 325. For example, memory unit 330-a may identify system data and may transfer the data to memory unit 330-b.

As a third example, memory array 330-b may additionally or alternatively store parity information or data associated with memory unit 315-a and memory array 330-a. Parity data may be used to rebuild corrupted data within a memory array 330, and the ability of parity data to be used to rebuild the corrupted data may increase when storing larger amounts of parity data. Parity data may include RAIN (redundant array of independent nodes) parity data, among other examples. Storing these larger amounts of data within memory unit 315-a may overload or tie up more memory within SRAM 365 or memory array 330-a, and as such, may be beneficially offloaded to memory array 330-b to free up memory space or to increase available memory storage space. For example, if memory storage for parity information is constrained, memory unit 315-a may temporarily cache parity information (e.g., temporary parity information) in memory array 330-b (e.g., in the non-volatile memory data cache 355). The information may be transferred from memory unit 315-b to memory unit 315-a via in-package interfaces 320-a and 320-b and one or more in-package channels 325. Memory array 330-b may have a higher performance and use lower power than memory array 330-a or SRAM 365, and may thus save power and increase memory usage efficiency when storing parity data or information. Any of the described examples herein may reduce processing time and complexity at the host device 305, as described with reference to the first example.

FIG. 4 illustrates an example of a process flow 400 that supports multichip memory packages in accordance with examples as disclosed herein. Process flow 400 may be implemented by a host device 405 that may be coupled with a memory device 410. Memory device 410 may be or include an MCP that includes multiple memory dice or memory arrays. For example, memory device 410 may include two or more memory units 415-a and 415-b, which may be examples of memory units described with reference to FIGS. 2 and 3 and may correspond to different types of memory. In some examples, memory unit 415-a may correspond to a type of non-volatile memory (e.g., NAND memory, ferroelectric memory, PCM, etc.) and memory unit 415-b may correspond to a type of volatile memory (e.g., RAM, DRAM, SDRAM, etc.). In some cases, a memory unit 415 may also include a controller, where a controller may be included on a separate die of the memory unit 415 or may share a die with portions of a memory array of the memory unit 415. As described with reference to FIGS. 2 and 3, a memory unit 415 may also include an in-package interface for communicating with one or more other memory units 415 of the memory device 410. The in-package interface may be coupled with one or more in-package channels, or physical entities (e.g., signal paths) associated with an in-package channel, that may support communications with the one or more other memory units 415.

In the following description of the process flow 400, the operations between any of the host device 405, the non-volatile memory unit 415-a, and the volatile memory unit 415-b may be transmitted in a different order than the order shown, or the operations performed by the host device 405, the non-volatile memory unit 415-a, and the volatile memory unit 415-b may be performed in different orders or at different times. Specific operations may also be left out of the process flow 400, or other operations may be added to the process flow 400. Although the host device 405, the non-volatile memory unit 415-a, and the volatile memory unit 415-b are shown performing the operations of process flow 400, some aspects of some operations may also be performed by another device. For example, a memory device 410 may include more than two memory units 415 and some of the operations of process flow 400 may be performed by other memory units 415 of the memory device 410.

At 420, the host device 405 may determine to initiate a read operation (e.g., with respect to memory unit 415-a) using the memory device 410. The read operation may include accessing data stored in the non-volatile memory unit 415-a and transferring the data directly to the volatile memory unit 415-b (e.g., without transferring data to the host device 405). Determining to initiate a read operation may be based on one or more processes being performed by the host device 405 or a system that includes the host device 405, in which the one or more processes may be performed based on reading the data from the non-volatile memory unit 415-a.

At 425, the host device 405 may transmit, to a controller for the non-volatile memory unit 415-a, a read command for the data stored in non-volatile memory of the non-volatile memory unit 415-a. In some cases, as described with reference to FIG. 2, the non-volatile memory may be included in a first die within the memory device 410 (e.g., within the package or MCP). In some examples, the read command may provide a pointer or an address (e.g., a logical address, a physical address, or both) for volatile memory of the volatile memory unit 415-b (e.g., in a main array or in a shared host data buffer) for storing the data associated with the read command. In some examples, the read command may include a pointer or an address for the non-volatile memory for accessing the data associated with the read command. In some cases, an address may include a logical block address, a length, and a pointer associated with one or more memory locations. In some cases, an address may include a logical address or a physical address, or both.

At 430, the non-volatile memory unit 415-a may read, in response to the read command, the data from the non-volatile memory. In some cases, the data may be read and stored by a controller of the non-volatile memory unit 415-a, which may further communicate with other portions of the memory device 410.

At 435, the non-volatile memory unit 415-a may transfer, after the reading and via a channel included within the memory device 410 (e.g., an in-package channel), the data from the controller for the non-volatile memory unit 415-a to the volatile memory unit 415-b. In some cases, the data may be transferred by a controller of the non-volatile memory unit 415-a. In some cases, as described with reference to FIG. 2, the volatile memory may be included in a second die within the memory device 410 (e.g., within the package or MCP). The non-volatile memory unit 415-a may also transmit control data to the volatile memory unit 415-b, which may indicate the address or pointer in the volatile memory to store the data, an amount of data, a request for a completion indication, or the like.

At 440, the volatile memory unit 415-b (e.g., a controller for the volatile memory unit 415-b) may store the data in the volatile memory based on the transferring. For example, the volatile memory unit 415-b may store the data at the address or pointer indicated in the read command (e.g., the specified memory location(s)). In some cases, the address or pointer in the read command may indicate for the data to be stored in the main array of the volatile memory unit 415-b or in the shared host data buffer of the volatile memory unit 415-b, and the volatile memory unit 415-b may store the data accordingly.

At 445, one or both of the non-volatile memory unit 415-a or the volatile memory unit 415-b may transmit an indication that the read command has been completed, based on transferring and/or storing the data.

FIG. 5 illustrates an example of a process flow 500 that supports multichip memory packages in accordance with examples as disclosed herein. Process flow 500 may be implemented by a host device 505 that may be coupled with a memory device 510. Memory device 510 may be or include an MCP that includes multiple memory dice or memory arrays. For example, memory device 510 may include two or more memory units 515-a and 515-b, which may be examples of memory units described with reference to FIGS. 2 and 3 and may correspond to different types of memory. In some examples, memory unit 515-a may correspond to a type of non-volatile memory (e.g., NAND memory, ferroelectric memory, PCM, etc.) and memory unit 515-b may correspond to a type of volatile memory (e.g., RAM, DRAM, SDRAM, etc.). In some cases, a memory unit 515 may also include a controller, where a controller may be included on a separate die of the memory unit 515 or may share a die with portions of a memory array of the memory unit 515. As described with reference to

FIGS. 2 and 3, a memory unit 515 may also include an in-package interface for communicating with one or more other memory units 515 of the memory device 510. The in-package interface may be coupled with one or more in-package channels, or physical entities associated with an in-package channel, that may support communications with the one or more other memory units 515.

In the following description of the process flow 500, the operations between any of the host device 505, the non-volatile memory unit 515-a, and the volatile memory unit 515-b may be transmitted in a different order than the order shown, or the operations performed by the host device 505, the non-volatile memory unit 515-a, and the volatile memory unit 515-b may be performed in different orders or at different times. Specific operations may also be left out of the process flow 500, or other operations may be added to the process flow 500. Although the host device 505, the non-volatile memory unit 515-a, and the volatile memory unit 515-b are shown performing the operations of process flow 500, some aspects of some operations may also be performed by another device. For example, a memory device 510 may include more than two memory units 515 and some of the operations of process flow 500 may be performed by other memory units 515 of the memory device 510.

At 520, the host device 505 may determine to initate a write operation using the memory device 510 (e.g., with respect to memory unit 515-a). The write operation may include accessing data stored in the volatile memory unit 515-b and directly transferring the data to the non-volatile memory unit 515-a (e.g., without transferring the data to the host device 505). Determining to initiate a write operation may be based on one or more processes being performed by the host device 505, or a system that includes the host device 505, in which the one or more processes may be performed based on writing the data to the non-volatile memory unit 515-a.

At 525, in some cases, the host device 505 may transfer data to the volatile memory unit 515-b. For example, the host device 505 may transfer the data to the volatile memory unit 515-b when running one or more applications or processes that are associated with the volatile memory unit 515-b (e.g., may transfer the data to perform one or more applications or processes at the host device 505 or at a system that includes the host device 505). In some cases, the data may be associated with a write operation (e.g., a future write operation). Though shown as occurring after 520, the host device 505 may have transferred the data to the volatile memory unit 515-b at any time, including before the determination at 520. In some examples, the host device 505 may indicate for the volatile memory unit 515-b to store the data in one or more memory locations (e.g., one or more logical or physical addresses, or both), and at 535, the volatile memory unit 515-b may store the data based on receiving the data from the host device 505. In some cases, as described with reference to FIG. 2, the volatile memory may be included in a second die within the memory device 510 (e.g., within the package or MCP).

At 530, the host device 505 may transmit, to a controller for the non-volatile memory unit 515-a, a write command for the data stored in the volatile memory. In some cases, as described with reference to FIG. 2, the non-volatile memory may be included in a first die within the memory device 510 (e.g., within the package or MCP). In some examples, the write command may provide a pointer or an address (e.g., a logical address, a physical address, or both) for the volatile memory (e.g., in a main array or in a shared host data buffer) for accessing the data associated with the write command. In some examples, the write command may include a pointer or an address for the non-volatile memory for storing the data associated with the write command. In some cases, an address may include a logical block address, a length, and a pointer associated with one or more memory locations. In some cases, an address may include a logical address or a physical address, or both.

At 540, the volatile memory unit 515-b may transfer, via a channel included within the memory device 510, the data from the volatile memory unit 515-b to the non-volatile memory unit 515-a. In some cases, the data may be transferred to a controller of the non-volatile memory unit 515-a and/or from a controller of the volatile memory unit 515-b.

In some cases, the non-volatile memory unit 515-a (e.g., a controller of the non-volatile memory unit 515-a) may request the data from the volatile memory unit 515-b and may receive the data based on the request. The volatile memory unit 515-b may also transmit control data to the volatile memory unit 515-a, which may indicate an amount of data, a request for a completion indication, or the like.

At 545, the non-volatile memory unit 515-a (e.g., a controller for the volatile memory unit 515-a) may write the data to the non-volatile memory based on the transferring. For example, the volatile memory unit 515-b may store the data at the address or pointer indicated in the write command (e.g., the specified memory location(s)). In some cases, the write command may omit an indication for the data to be stored in a specific location of the non-volatile memory, and the controller of the non-volatile memory unit 515-a may determine a location to store the data. In some cases, the non-volatile memory unit 515-a may store the data if a cache of the non-volatile memory unit 515-a is on, or may wait to store the data until the cache is on.

At 550, one or both of the non-volatile memory unit 515-a or the volatile memory unit 515-b may transmit an indication that the write command has been completed, based on transferring and/or storing the data. In one example, if a cache of the non-volatile memory unit 515-a is on, the non-volatile memory unit 515-a may signal the host device 505 after storing the data. In another example, if a cache of the non-volatile memory unit 515-a is off, the non-volatile memory unit 515-a (e.g., the controller of the non-volatile memory unit 515-a) may signal the host device 505 after receiving the data transfer from the volatile memory unit 515-b.

FIG. 6 shows a block diagram 600 of a memory device 605 that supports multichip memory packages in accordance with examples as disclosed herein. The memory device 605 may be an example of aspects of a memory device as described with reference to FIGS. 1-5. The memory device 605 may include a read command component 610, a non-volatile memory component 615, a data transfer component 620, a volatile memory component 625, a write command component 630, a completion indication component 635, and a memory address component 640. Each of these modules may communicate, directly or indirectly, with one another (e.g., via one or more buses).

The read command component 610 may receive, at a controller for non-volatile memory within a package, a read command for data stored in the non-volatile memory, the non-volatile memory included in a first die within the package. The non-volatile memory component 615 may read, by the controller for the non-volatile memory and in response to the read command, the data from the non-volatile memory in the first die. In some examples, the non-volatile memory component 615 may write, based on the transferring, the data to the non-volatile memory in the first die.

The data transfer component 620 may transfer, after the reading and via a channel included within the package, the data from the controller for the non-volatile memory to volatile memory included in a second die within the package. In some examples, the data transfer component 620 may transfer, in response to the write command and via a channel included within the package, the data from the volatile memory in the second die to the controller for the non-volatile memory.

In some cases, the second die includes a second controller for the volatile memory, and where the second controller is coupled with the controller for the non-volatile memory via the channel. In some cases, the second die includes a second controller for the volatile memory, and where the transferring is between the second controller and the controller for the non-volatile memory.

The volatile memory component 625 may store, based on the transferring, the data in the volatile memory in the second die. The write command component 630 may receive, at a controller for non-volatile memory within a package, a write command for data stored in volatile memory, where the non-volatile memory is included in a first die within the package and the volatile memory is included in a second die within the package. The completion indication component 635 may transmit an indication that the read command has been completed based on the transferring. In some examples, the completion indication component 635 may transmit an indication that the write command has been completed based on the writing.

The memory address component 640 may read the data from the non-volatile memory in the first die based on the first address. In some examples, the memory address component 640 may store the data in the volatile memory in the second die based on the second address. In some examples, the memory address component 640 may read the data from the volatile memory in the second die based on the write command and the address. In some examples, the memory address component 640 may write the data to the non-volatile memory in the first die based on the logical address. In some cases, the read command indicates a first address associated with the non-volatile memory in the first die and a second address associated with the volatile memory in the second die. In some cases, the first address includes a logical address associated with the data stored in the non-volatile memory in the first die. In some cases, the second address includes a physical address associated with the volatile memory in the second die. In some cases, the first address includes a logical address associated with the data stored in the non-volatile memory in the first die. In some cases, the second address includes a logical address associated with the volatile memory in the second die. In some cases, the address includes a logical address or a physical address associated with the data stored in the volatile memory in the second die.

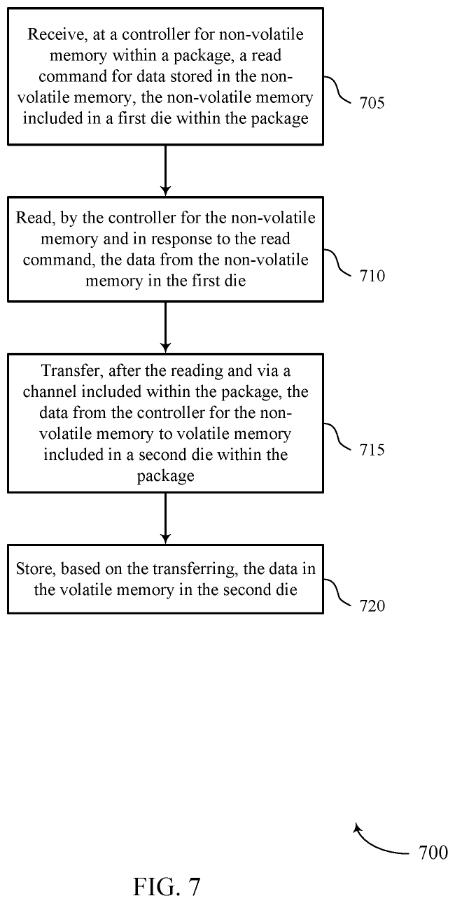

FIG. 7 shows a flowchart illustrating a method or methods 700 that supports multichip memory packages in accordance with aspects of the present disclosure. The operations of method 700 may be implemented by a memory device or its components as described herein. For example, the operations of method 700 may be performed by a memory device as described with reference to FIG. 6. In some examples, a memory device may execute a set of instructions to control the functional elements of the memory device to perform the described functions. Additionally or alternatively, a memory device may perform aspects of the described functions using special-purpose hardware.

At 705, the memory device may receive, at a controller for non-volatile memory within a package, a read command for data stored in the non-volatile memory, the non-volatile memory included in a first die within the package. The operations of 705 may be performed according to the methods described herein. In some examples, aspects of the operations of 705 may be performed by a read command component as described with reference to FIG. 6.

At 710, the memory device may read, by the controller for the non-volatile memory and in response to the read command, the data from the non-volatile memory in the first die. The operations of 710 may be performed according to the methods described herein.

In some examples, aspects of the operations of 710 may be performed by a non-volatile memory component as described with reference to FIG. 6.

At 715, the memory device may transfer, after the reading and via a channel included within the package, the data from the controller for the non-volatile memory to volatile memory included in a second die within the package. The operations of 715 may be performed according to the methods described herein. In some examples, aspects of the operations of 715 may be performed by a data transfer component as described with reference to FIG. 6.

At 720, the memory device may store, based on the transferring, the data in the volatile memory in the second die. The operations of 720 may be performed according to the methods described herein. In some examples, aspects of the operations of 720 may be performed by a volatile memory component as described with reference to FIG. 6.

In some examples, an apparatus as described herein may perform a method or methods, such as the method 700. The apparatus may include features, means, or instructions (e.g., a non-transitory computer-readable medium storing instructions executable by a processor) for receiving, at a controller for non-volatile memory within a package, a read command for data stored in the non-volatile memory, the non-volatile memory included in a first die within the package, reading, by the controller for the non-volatile memory and in response to the read command, the data from the non-volatile memory in the first die, transferring, after the reading and via a channel included within the package, the data from the controller for the non-volatile memory to volatile memory included in a second die within the package, and storing, based on the transferring, the data in the volatile memory in the second die.

In some examples of the method 700 and the apparatus described herein, the read command indicates a first address associated with the non-volatile memory in the first die and a second address associated with the volatile memory in the second die.

Some examples of the method 700 and the apparatus described herein may further include operations, features, means, or instructions for reading the data from the non-volatile memory in the first die based on the first address, and storing the data in the volatile memory in the second die based on the second address.

In some examples of the method 700 and the apparatus described herein, the first address includes a logical address associated with the data stored in the non-volatile memory in the first die, and the second address includes a physical address associated with the volatile memory in the second die.

In some examples of the method 700 and the apparatus described herein, the first address includes a logical address associated with the data stored in the non-volatile memory in the first die, and the second address includes a logical address associated with the volatile memory in the second die.

In some examples of the method 700 and the apparatus described herein, the second die includes a second controller for the volatile memory, and where the second controller may be coupled with the controller for the non-volatile memory via the channel.

Some examples of the method 700 and the apparatus described herein may further include operations, features, means, or instructions for transmitting an indication that the read command may have been completed based on the transferring.

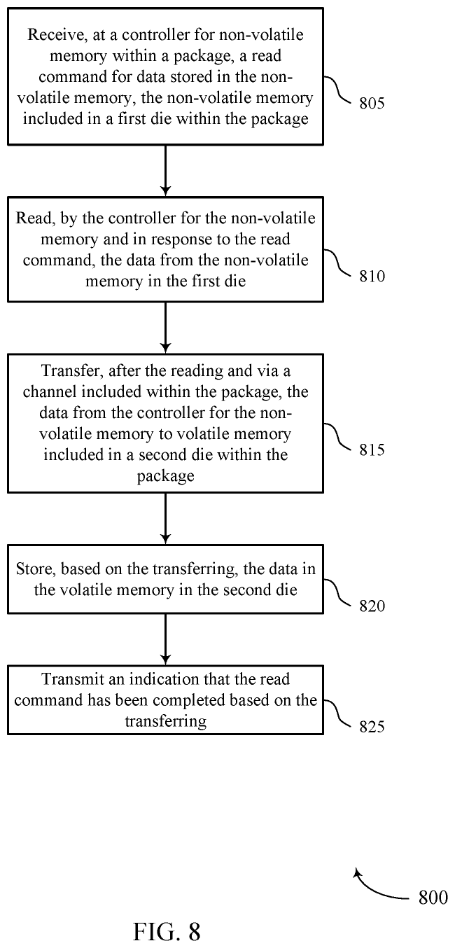

FIG. 8 shows a flowchart illustrating a method or methods 800 that supports multichip memory packages in accordance with aspects of the present disclosure. The operations of method 800 may be implemented by a memory device or its components as described herein. For example, the operations of method 800 may be performed by a memory device as described with reference to FIG. 6. In some examples, a memory device may execute a set of instructions to control the functional elements of the memory device to perform the described functions. Additionally or alternatively, a memory device may perform aspects of the described functions using special-purpose hardware.

At 805, the memory device may receive, at a controller for non-volatile memory within a package, a read command for data stored in the non-volatile memory, the non-volatile memory included in a first die within the package. The operations of 805 may be performed according to the methods described herein. In some examples, aspects of the operations of 805 may be performed by a read command component as described with reference to FIG. 6.

At 810, the memory device may read, by the controller for the non-volatile memory and in response to the read command, the data from the non-volatile memory in the first die. The operations of 810 may be performed according to the methods described herein.

In some examples, aspects of the operations of 810 may be performed by a non-volatile memory component as described with reference to FIG. 6.

At 815, the memory device may transfer, after the reading and via a channel included within the package, the data from the controller for the non-volatile memory to volatile memory included in a second die within the package. The operations of 815 may be performed according to the methods described herein. In some examples, aspects of the operations of 815 may be performed by a data transfer component as described with reference to FIG. 6.

At 820, the memory device may store, based on the transferring, the data in the volatile memory in the second die. The operations of 820 may be performed according to the methods described herein. In some examples, aspects of the operations of 820 may be performed by a volatile memory component as described with reference to FIG. 6.

At 825, the memory device may transmit an indication that the read command has been completed based on the transferring. The operations of 825 may be performed according to the methods described herein. In some examples, aspects of the operations of 825 may be performed by a completion indication component as described with reference to FIG. 6.

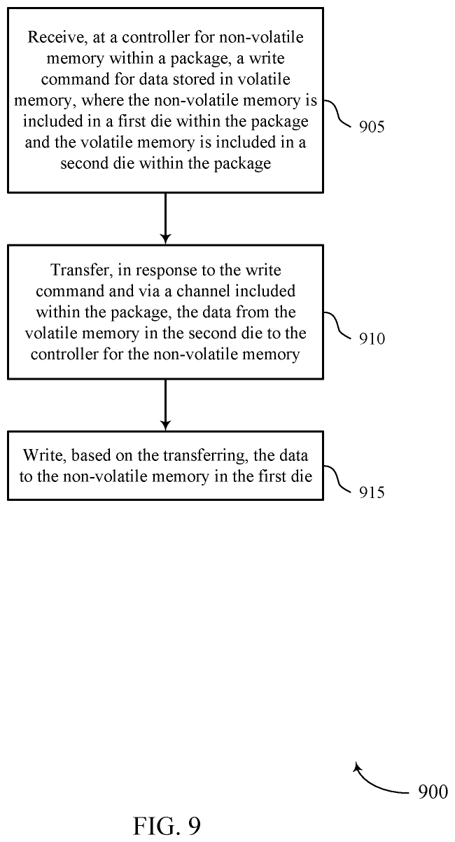

FIG. 9 shows a flowchart illustrating a method or methods 900 that supports multichip memory packages in accordance with aspects of the present disclosure. The operations of method 900 may be implemented by a memory device or its components as described herein. For example, the operations of method 900 may be performed by a memory device as described with reference to FIG. 6. In some examples, a memory device may execute a set of instructions to control the functional elements of the memory device to perform the described functions. Additionally or alternatively, a memory device may perform aspects of the described functions using special-purpose hardware.

At 905, the memory device may receive, at a controller for non-volatile memory within a package, a write command for data stored in volatile memory, where the non-volatile memory is included in a first die within the package and the volatile memory is included in a second die within the package. The operations of 905 may be performed according to the methods described herein. In some examples, aspects of the operations of 905 may be performed by a write command component as described with reference to FIG. 6.

At 910, the memory device may transfer, in response to the write command and via a channel included within the package, the data from the volatile memory in the second die to the controller for the non-volatile memory. The operations of 910 may be performed according to the methods described herein. In some examples, aspects of the operations of 910 may be performed by a data transfer component as described with reference to FIG. 6.

At 915, the memory device may write, based on the transferring, the data to the non-volatile memory in the first die. The operations of 915 may be performed according to the methods described herein. In some examples, aspects of the operations of 915 may be performed by a non-volatile memory component as described with reference to FIG. 6.

In some examples, an apparatus as described herein may perform a method or methods, such as the method 900. The apparatus may include features, means, or instructions (e.g., a non-transitory computer-readable medium storing instructions executable by a processor) for receiving, at a controller for non-volatile memory within a package, a write command for data stored in volatile memory, where the non-volatile memory is included in a first die within the package and the volatile memory is included in a second die within the package, transferring, in response to the write command and via a channel included within the package, the data from the volatile memory in the second die to the controller for the non-volatile memory, and writing, based on the transferring, the data to the non-volatile memory in the first die.

Some examples of the method 900 and the apparatus described herein may further include operations, features, means, or instructions for reading the data from the volatile memory in the second die based on the write command and the address.

In some examples of the method 900 and the apparatus described herein, the address includes a logical address or a physical address associated with the data stored in the volatile memory in the second die.

Some examples of the method 900 and the apparatus described herein may further include operations, features, means, or instructions for writing the data to the non-volatile memory in the first die based on the logical address.

In some examples of the method 900 and the apparatus described herein, the second die includes a second controller for the volatile memory, and where the transferring may be between the second controller and the controller for the non-volatile memory.

Some examples of the method 900 and the apparatus described herein may further include operations, features, means, or instructions for transmitting an indication that the write command may have been completed based on the writing.

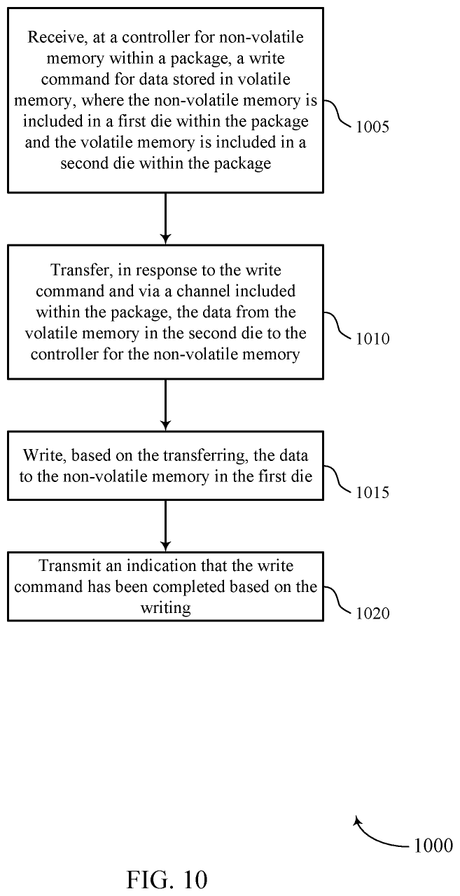

FIG. 10 shows a flowchart illustrating a method or methods 1000 that supports multichip memory packages in accordance with aspects of the present disclosure. The operations of method 1000 may be implemented by a memory device or its components as described herein. For example, the operations of method 1000 may be performed by a memory device as described with reference to FIG. 6. In some examples, a memory device may execute a set of instructions to control the functional elements of the memory device to perform the described functions. Additionally or alternatively, a memory device may perform aspects of the described functions using special-purpose hardware.

At 1005, the memory device may receive, at a controller for non-volatile memory within a package, a write command for data stored in volatile memory, where the non-volatile memory is included in a first die within the package and the volatile memory is included in a second die within the package. The operations of 1005 may be performed according to the methods described herein. In some examples, aspects of the operations of 1005 may be performed by a write command component as described with reference to FIG. 6.

At 1010, the memory device may transfer, in response to the write command and via a channel included within the package, the data from the volatile memory in the second die to the controller for the non-volatile memory. The operations of 1010 may be performed according to the methods described herein. In some examples, aspects of the operations of 1010 may be performed by a data transfer component as described with reference to FIG. 6.

At 1015, the memory device may write, based on the transferring, the data to the non-volatile memory in the first die. The operations of 1015 may be performed according to the methods described herein. In some examples, aspects of the operations of 1015 may be performed by a non-volatile memory component as described with reference to FIG. 6.

At 1020, the memory device may transmit an indication that the write command has been completed based on the writing. The operations of 1020 may be performed according to the methods described herein. In some examples, aspects of the operations of 1020 may be performed by a completion indication component as described with reference to FIG. 6.

It should be noted that the methods described herein are possible implementations, and that the operations and the steps may be rearranged or otherwise modified and that other implementations are possible. Furthermore, portions from two or more of the methods may be combined.

An apparatus is described. The apparatus may include a first die within a package and including non-volatile memory, a second die within the package and including volatile memory, a controller for the non-volatile memory, the controller within the package and coupled with the non-volatile memory, and a channel within the package and configured to carry data between the controller for the non-volatile memory and the volatile memory in the second die.

Some examples of the apparatus may include a second controller for the volatile memory, the second controller included in the second die, where the channel may be configured to carry data between the controller for the non-volatile memory and the second controller for the volatile memory. Some examples of the apparatus may include a third die within the package, where the controller for the non-volatile memory may be included in the third die.

Some examples of the apparatus may include an interface operable to couple the controller for the non-volatile memory with a host device for the apparatus, where the controller for the non-volatile memory may be operable to receive, via the interface, a read command from the host device for first data stored in the non-volatile memory in the first die, the read command indicating a first address associated with the non-volatile memory in the first die and a second address associated with the volatile memory in the second die. The controller for the non-volatile memory may be further operable to read the first data from the non-volatile memory in the first die based on the first address and transmit, via the channel within the package, the first data and an indication of the second address to the second die.

Some examples of the apparatus may include an interface operable to couple the controller for the non-volatile memory with a host device for the apparatus, where the controller for the non-volatile memory may be operable to receive, via the interface, a write command from the host device for first data stored in the volatile memory in the second die, the write command indicating a first address associated with the volatile memory in the second die and a second address associated with the non-volatile memory in the first die. The controller for the non-volatile memory may be further operable to obtain, via the channel within the package, the first data from the volatile memory in the second die based on the first address and write the first data to the non-volatile memory in the first die based on the second address.

In some examples, a portion of the volatile memory in the second die includes a dedicated cache for the controller for the non-volatile memory. In some examples, a second portion of the volatile memory in the second die may be operable to be accessed by the controller for the non-volatile memory and by a host device for the apparatus. Some examples may further include determining mapping information that relates logical addresses for data stored in the non-volatile memory to physical addresses for the non-volatile memory in the first die, and transmit, via the channel within the package, the mapping information to the volatile memory in the second die, where the volatile memory in the second die may be operable to store the mapping information. Some examples may further include determining parity information for data stored in the non-volatile memory in the first die, and transmit, via the channel within the package, the parity information to the volatile memory in the second die, where the volatile memory in the second die may be operable to store the parity information.

Some examples may further include receiving a first command to enter a low power mode, transmitting, to the volatile memory in the second die via the channel within the package and in response to the first command, state information for the non-volatile memory in the first die, where the volatile memory in the second die may be operable to store the state information for the non-volatile memory in the first die, receiving a second command to exit the low power mode, and receiving, via the channel within the package and in response to the second command, the state information from the second die.

In some examples, the non-volatile memory in the first die includes NAND memory, and the volatile memory in the second die includes DRAM. In some examples, the first die and the second die may be both coupled with a same substrate.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

As used herein, the term “virtual ground” refers to a node of an electrical circuit that is held at a voltage of approximately zero volts (0V) but that is not directly coupled with ground. Accordingly, the voltage of a virtual ground may temporarily fluctuate and return to approximately 0V at steady state. A virtual ground may be implemented using various electronic circuit elements, such as a voltage divider consisting of operational amplifiers and resistors. Other implementations are also possible. “Virtual grounding” or “virtually grounded” means connected to approximately 0V.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some cases, the flow of signals between the connected components may be interrupted for a time, for example, using one or more intermediate components such as switches or transistors.

The term “coupling” refers to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

As used herein, the term “substantially” means that the modified characteristic (e.g., a verb or adjective modified by the term substantially) need not be absolute but is close enough to achieve the advantages of the characteristic.

The devices discussed herein, including a memory array, may be formed on a semiconductor substrate, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are signals), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to providing an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The various illustrative blocks and modules described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations. Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM,

ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor.

Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An apparatus, comprising:
a first die within a package and comprising non-volatile memory;
a second die within the package and comprising volatile memory;
a controller for the non-volatile memory, the controller within the package and coupled with the non-volatile memory; and
a channel within the package and configured to carry data between the controller for the non-volatile memory and the volatile memory in the second die.

2. The apparatus of claim 1, further comprising:
a second controller for the volatile memory, the second controller included in the second die, wherein the channel is configured to carry data between the controller for the non-volatile memory and the second controller for the volatile memory.

3. The apparatus of claim 1, further comprising:
a third die within the package, wherein the controller for the non-volatile memory is included in the third die.

4. The apparatus of claim 1, further comprising:
an interface operable to couple the controller for the non-volatile memory with a host device for the apparatus, wherein the controller for the non-volatile memory is operable to:
receive, via the interface, a read command from the host device for first data stored in the non-volatile memory in the first die, the read command indicating a first address associated with the non-volatile memory in the first die and a second address associated with the volatile memory in the second die;
read the first data from the non-volatile memory in the first die based at least in part on the first address; and
transmit, via the channel within the package, the first data and an indication of the second address to the second die.

5. The apparatus of claim 1, further comprising:
an interface operable to couple the controller for the non-volatile memory with a host device for the apparatus, wherein the controller for the non-volatile memory is operable to:
receive, via the interface, a write command from the host device for first data stored in the volatile memory in the second die, the write command indicating a first address associated with the volatile memory in the second die and a second address associated with the non-volatile memory in the first die;
obtain, via the channel within the package, the first data from the volatile memory in the second die based at least in part on the first address; and
write the first data to the non-volatile memory in the first die based at least in part on the second address.

6. The apparatus of claim 1, wherein a portion of the volatile memory in the second die comprises a dedicated cache for the controller for the non-volatile memory.

7. The apparatus of claim 6, wherein a second portion of the volatile memory in the second die is operable to be accessed by the controller for the non-volatile memory and by a host device for the apparatus.

8. The apparatus of claim 1, wherein the controller for the non-volatile memory is operable to:
determine mapping information that relates logical addresses for data stored in the non-volatile memory to physical addresses for the non-volatile memory in the first die; and
transmit, via the channel within the package, the mapping information to the volatile memory in the second die, wherein the volatile memory in the second die is operable to store the mapping information.

9. The apparatus of claim 1, wherein the controller for the non-volatile memory is operable to:
determine parity information for data stored in the non-volatile memory in the first die; and
transmit, via the channel within the package, the parity information to the volatile memory in the second die, wherein the volatile memory in the second die is operable to store the parity information.

10. The apparatus of claim 1, wherein the controller for the non-volatile memory is operable to:
receive a first command to enter a low power mode;
transmit, to the volatile memory in the second die via the channel within the package and in response to the first command, state information for the non-volatile memory in the first die, wherein the volatile memory in the second die is operable to store the state information for the non-volatile memory in the first die;
receive a second command to exit the low power mode; and
receive, via the channel within the package and in response to the second command, the state information from the second die.

11. The apparatus of claim 1, wherein:
the non-volatile memory in the first die comprises not-and (NAND) memory; and
the volatile memory in the second die comprises dynamic random access memory (DRAM).

12. The apparatus of claim 1, wherein the first die and the second die are both coupled with a same substrate.

13. A method, comprising:
receiving, at a controller for non-volatile memory within a package, a read command for data stored in the non-volatile memory, the non-volatile memory included in a first die within the package;
reading, by the controller for the non-volatile memory and in response to the read command, the data from the non-volatile memory in the first die;
transferring, after the reading and via a channel included within the package, the data from the controller for the non-volatile memory to volatile memory included in a second die within the package; and
storing, based at least in part on the transferring, the data in the volatile memory in the second die.

14. The method of claim 13, wherein the read command indicates a first address associated with the non-volatile memory in the first die and a second address associated with the volatile memory in the second die.

15. The method of claim 14, further comprising:
reading the data from the non-volatile memory in the first die based at least in part on the first address; and
storing the data in the volatile memory in the second die based at least in part on the second address.

16. The method of claim 14, wherein:
the first address comprises a logical address associated with the data stored in the non-volatile memory in the first die; and
the second address comprises a physical address associated with the volatile memory in the second die.

17. The method of claim 14, wherein:
the first address comprises a logical address associated with the data stored in the non-volatile memory in the first die; and
the second address comprises a logical address associated with the volatile memory in the second die.

18. The method of claim 14, wherein the second die includes a second controller for the volatile memory, and wherein the second controller is coupled with the controller for the non-volatile memory via the channel.

19. The method of claim 13, further comprising:
transmitting an indication that the read command has been completed based at least in part on the transferring.

20. A method, comprising:
receiving, at a controller for non-volatile memory within a package, a write command for data stored in volatile memory, wherein the non-volatile memory is included in a first die within the package and the volatile memory is included in a second die within the package;
transferring, in response to the write command and via a channel included within the package, the data from the volatile memory in the second die to the controller for the non-volatile memory; and
writing, based at least in part on the transferring, the data to the non-volatile memory in the first die.

21. The method of claim 20, wherein the write command indicates an address associated with the volatile memory in the second die, further comprising:
reading the data from the volatile memory in the second die based at least in part on the write command and the address.

22. The method of claim 21, wherein the address comprises a logical address or a physical address associated with the data stored in the volatile memory in the second die.

23. The method of claim 20, wherein the write command indicates a logical address associated with the non-volatile memory in the first die, further comprising:
writing the data to the non-volatile memory in the first die based at least in part on the logical address.

24. The method of claim 20, wherein the second die includes a second controller for the volatile memory, and wherein the transferring is between the second controller and the controller for the non-volatile memory.

25. The method of claim 20, further comprising:
transmitting an indication that the write command has been completed based at least in part on the writing.
